(19) United States
(12) Patent Application Publication
(10) Pub. No.: US 2010/0059269 A1
(43) Pub. Date: Mar. 11, 2010

(54) Electrical Equipment Receptacle Cover

(75) Inventor: Richard A. Rivkin, Deerfield, IL (US)

Correspondence Address: MCHALE & SLAVIN, P.A., 2855 PGA BLVD, PALM BEACH GARDENS, FL, 33410, US

(73) Assignee: Saf-T-Gard International, Inc., Northbrook, IL (US)

(21) Appl. No.: 12/283,006

(22) Filed: Sep. 9, 2008

(51) Int. Cl. H01L 23/28

(52) U.S. Cl. 174/521

(57) ABSTRACT

A soft rubber protective safety cover for positioning over a projecting receptacle portion of an electrical equipment box to minimize the safety hazard caused by such projecting portion. The cover is of generally cylindrical configuration with oppositely disposed generally rectangular portions positioned along the elongate dimension of the cover to encapsulate the receptacle when the cover is in position thereover so as to prevent sharp and/or projecting portions thereof from causing injury to a person who comes in contact with the receptacle.

### BACKGROUND OF THE INVENTION

1. Field of the Invention

This invention relates generally to covers for electrical equipment receptacles, and more particularly, to such covers intended to be positioned over protruding receptacle portions of heavy duty electrical equipment so as to minimize a safety hazard caused by such protruding receptacle portions.

2. Description of the Related Art

Electrical equipment of the type usually used in outdoor installations, such as for cell telephone towers, commonly includes a distribution panel box to retain electrical components of the equipment. It also is common for such panel boxes to have as a component thereof a receptacle intended to receive, when needed, a plug connector intended to supply auxiliary power to the cell tower for its continued operation in the event that the usually applied utility company power supply is interrupted. The receptacle positioned on many such panel boxes is in the form of a projecting adapter of generally cylindrical configuration having a cap normally secured thereon by removable, somewhat sharp edged, fasteners to protect the electrical components contained within the receptacle from weather, debris and the like until it is necessary to remove the cap by withdrawing the fasteners to enable access to the electrical components, such as for securing an auxiliary power supply connector thereto.

The projecting receptacles, as well as the somewhat sharp edged fasteners associated therewith, have been known to present a safety hazard for workers who regularly function and perform operations around and about the electrical equipment during normal service activities. The receptacle and associated fastener parts commonly are formed of metal or other rigid material and, when accidentally bumped or scraped against by a worker, can result in various degrees of injury.

Accordingly, it is desirable to provide an electrical equipment receptacle cover formed of relatively soft rubber material for removable positioning over the receptacle to encapsulate the receptacle and its associated relatively sharp edged fasteners to prevent the same from causing injury to a person who comes in contact with the receptacle

### SUMMARY OF THE INVENTION

The invention is characterized by a cover formed of relatively soft rubber material of generally cylindrical configuration having an open end adapted to be slidably positioned over the projecting receptacle portion of an electrical equipment box. The cover includes a closed end spaced at a distance from the open end such that the cover encloses the receptacle portion when the cover is positioned thereover. The cover is formed with a pair of generally rectangular shaped extension portions disposed along opposite sides of the elongate length of the cover, each extension portion having a respective open end coextensive with the open end of the cover, and a closed end spaced beyond the plane of the closed end of the cover. The configuration of the cover and the closed ends of the extension portions is such that, when the cover is positioned over the receptacle portion of the electrical equipment box, any sharp and/or projecting portions thereof are prevented from causing injury to a person who comes in contact with the receptacle.

Various objects and advantages of the invention will become apparent in accordance with the above and ensuing disclosure in which the preferred embodiments are described in detail in the specification and illustrated in the accompanying drawings. It is contemplated that minor variations may occur to persons skilled in the art without departing from the scope or sacrificing any of the advantages of the invention.

### BRIEF DESCRIPTION OF THE DRAWINGS

FIG. 1 is a front/top/left side/bottom perspective view of the electrical equipment receptacle cover of the invention, the same being illustrated proximate to an electrical equipment box with projecting receptacle upon and over which the cover is intended to be slidably positioned;

FIG. 2 is a perspective view similar to that of FIG. 1, showing the electrical equipment receptacle cover in position over the projecting receptacle of the electrical equipment box;

FIG. 3 is a rear/top/left side/bottom perspective view of the cover of the invention;

FIG. 4 is a sectional view taken along the line 4-4 of FIG. 2 in the direction indicated generally;

FIG. 5 is a perspective view of a hook and loop tape fastener for use with the cover of the invention;

FIG. 6 is a perspective view similar to that of FIG. 2, showing the tape fastener of FIG. 5 in place over the cover of the invention in a manner to secure the cover in its position over the receptacle; and

FIG. 7 is a perspective view similar to that of FIG. 3, with the cover being shown in partial section to illustrate an alternate embodiment in which water drainage apertures are formed in a portion of the cover.

### DETAILED DESCRIPTION OF THE INVENTION

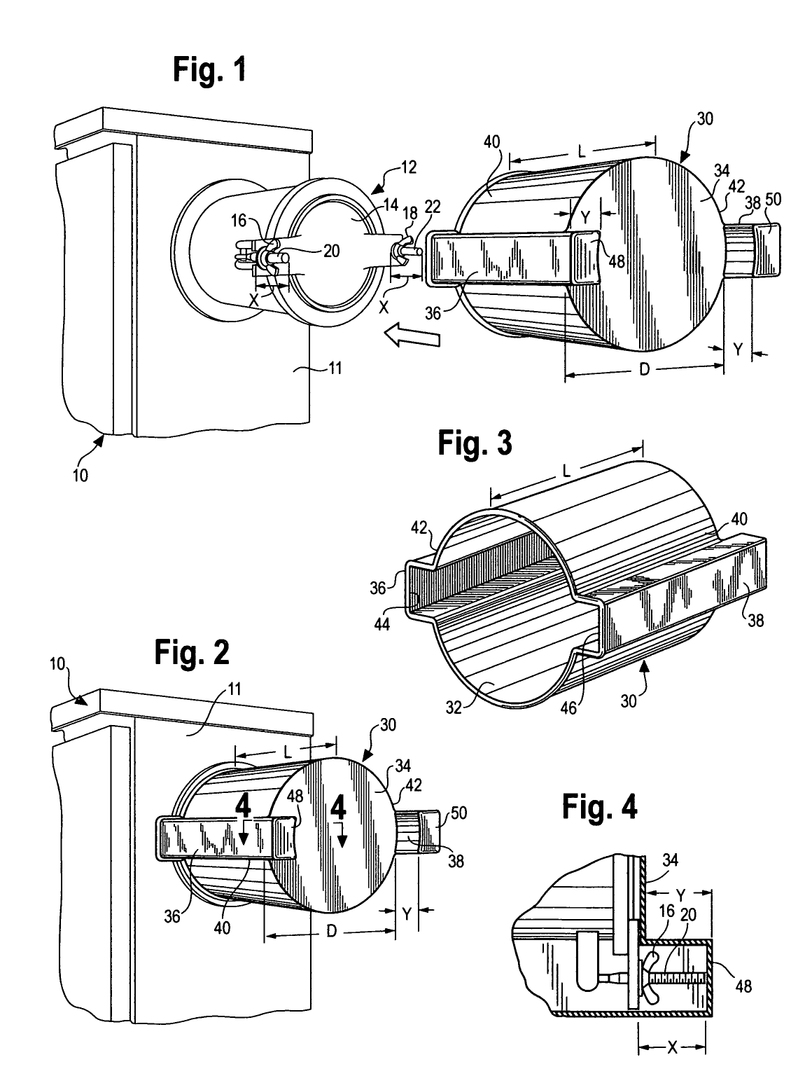

Referring to the drawings, FIG. 1 illustrates an electrical equipment distribution panel box 10 of the type commonly used in outdoor installations, such as for cell telephone towers. Although reference is made herein to an electrical equipment box of the type used with a cell telephone tower, it is to be understood that such equipment for use with any type of installation is contemplated for use in connection with the invention herein; the illustrated panel box 10 and its associated elements are one example only of the type of equipment with which the invention is adapted for use.

The electrical equipment retained within the panel box 10 for operating the associated equipment, i.e., a cell telephone tower, usually is supplied with power provided by a utility company by conventionally associated power lines (not shown). In the event that the power provided to the electrical equipment by a utility company becomes interrupted, such as by damaging storms or by other types of power line damage, cell telephone towers commonly are provided with means to supply an alternate source of electrical power thereto, such as by conventional portable generator equipment. Such portable generator equipment (not shown), when positioned adjacent to the panel box 10, is connected to the electrical components retained within the panel box by a plug for insertion into a mating socket installed within the box. The mating socket for the electrical equipment commonly is retained within a receptacle 12 mounted on the box 10 adjacent surface 11 of the box, which receptacle is provided with a cap 14 normally secured thereto by fasteners 16, 18 which can be removed to enable withdrawal of the cap so that the socket retained within the receptacle is accessible for the auxiliary power supply plug to be applied to the socket to power the cell tower. For purposes of illustration only, the receptacle 12 depicts an Appleton Electric 200 amp generator receptacle and associated parts.

The receptacle 12 positioned on cell tower panel box 10, and many like receptacles associated with other types of panel boxes, is in the form of a projecting member of generally cylindrical configuration with its associated cap 14 secured by fasteners 16, 18 that have somewhat sharp edges. For example, the fasteners 16, 18 are illustrated as wing nuts secured to respective projecting bolts 20, 22 that extend a distance “X” beyond the plane of the cap 14. The receptacle 12, cap 14, fasteners 16, 18 and bolts 20, 22 commonly are formed of metal or other rigid material and thereby present a safety hazard for workers who regularly function and perform operations around and about the electrical equipment during normal service activities in that, when they are accidentally bumped or scraped against by such workers, they can result in various degrees of injury. The receptacle cover of the invention is provided to prevent the occurrence of such injuries.

The electrical equipment receptacle cover 30 of the invention is formed of relatively soft rubber material. Any suitable soft rubber material is contemplated by the invention, but preferably is a synthetic compound that is sunlight and chemical resistant suitable for outdoor applications in connection with heavy duty equipment. Preferably, the cover 30 is formed of ethylene propylene diene M-class rubber (EPDM rubber), but any other soft rubber material may be used.

Cover 30 is of generally cylindrical configuration with a diameter D and an elongate length L and includes an open end 32 and a closed end 34 spaced from the open end a distance which is approximately equal to the length of the receptacle 12 between its connection with panel box 10 at surface 11 and the extremities of bolts 20, 22 upon which fasteners 16, 18 are secured. Cover 30 is formed with a pair of generally rectangular shaped extension portions 36, 38 disposed proximate the diameter D along opposite sides 40,42 of the elongate length L of the cover. Each extension portion 36,38 has a respective open end 44, 46. Each open end 44,46 is coextensive with the open end 32 of the cover 30. Each extension portion 36, 38 has a respective closed end 48, 50 spaced from the open ends 44, 46 and projecting a distance “Y” beyond the plane of the closed end 34 of cover 30. In the preferred embodiment, the distance “Y” that the closed ends 48, 50 of extensions 36, 38 project beyond the plane of the closed end 34 of cover 30 is approximately equal to the distance “X” that the bolts 20, 22 extend beyond the plane of cap 14 of receptacle 12.

As illustrated in FIG. 1, receptacle cover 30 is adapted to be slidably positioned over receptacle 12 with the receptacle encapsulated within the confines of the cylindrical configured cover. During such positioning, the fasteners 16, 18 with associated projecting bolts 20, 22 slide within the confines of extension portions 36, 38 and, when the cover is completely positioned over receptacle 12 with open end 32 of the cover abutting the surface 11 of box 10, the fasteners and bolts are contained within the closed ends 48, 50 of extensions 36, 38. Thereby, the sharp and projecting bolts and fasteners, as well as the entire receptacle 12, are encased by the soft rubber cover 30 to prevent the same from causing injury to a person who comes in contact therewith. The cover 30 is intended to remain in place over the receptacle 12 until access to the receptacle is desired, at which time the cover is removable merely by withdrawing same from its position over the receptacle.

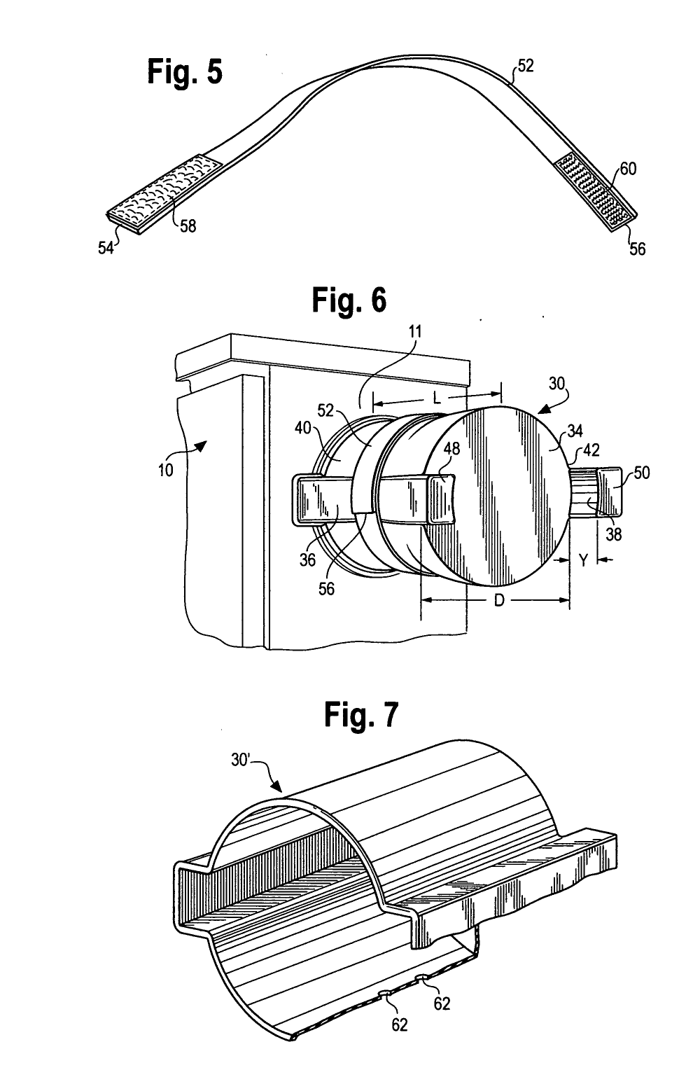

FIGS. 5 and 6 of the drawings illustrate a means of securing the cover 30 to the receptacle positioned upon box 10. An elongate tape fastener 52 of any flexible material, such as sturdy cloth, is provided for application about the circumference of cover 30 at any convenient location along length L after the cover is positioned upon the receptacle. The ends 54, 56 of tape 52 may be removably retained together by conventional hook and loop fasteners 58, 60. The hook and loop fasteners are shown for purposes of illustration only; any other fastening means for the ends of tape 52 are within the contemplated scope of the invention. Also, any alternate means of securing the cover 30 to the receptacle 12 are contemplated by the invention.

FIG. 7 illustrates an alternate embodiment of the invention, in which one or more apertures 62 may be formed at any suitable location along the length L of the cover 30′ to permit drainage of water which may accumulate within the confines of the cover while it is installed upon the receptacle 12.

Although the dimensions of the cover 30 and associated elements may vary within the scope of the invention, in the preferred embodiment the length L is 5½ inches, diameter D is 5½ inches, projecting distance “Y” is 1 inch and the cross sectional dimension of each extension portion 36, 38 is 1 inch wide by 1¾ inch high. The preferred dimensions of the tape fastener 52 are 22 inches long by ¾ inch wide, with the hook and loop fastener portions extending 4 inches from the respective ends of the tape, but the dimensions of the tape fastener 52 may vary depending upon the dimensions of the cover 30.

Other configurations and variations in the structure, arrangement and size of the various parts may occur to those skilled in the art without departing from the spirit or circumventing the scope of the invention as set forth in the appended claims.

What is claimed is:

1. A cover for an electrical equipment receptacle which includes a length having projecting portions extending beyond a surface of the receptacle, said cover comprising, a body having an elongate length, said body having an open end and a closed end, the closed end being positioned within a plane spaced from the open end, a pair of extension portions disposed along opposite sides of the elongate length, each said extension portion having a respective open end coextensive with the open end of the cover and a closed end spaced beyond the plane of the closed end of the cover, the cover being adapted to be slidably positioned over the receptacle such that when the cover is so positioned the projecting portions of the receptacle are confined within the cover.

2. A cover as claimed in claim 1 in which the body is of generally cylindrical configuration.

3. A cover as claimed in claim 2 in which the elongate length of the cover is approximately equal to the length of the receptacle.

4. A cover as claimed in claim 3 in which the projecting portions of the receptacle extend a fixed distance beyond said surface of the receptacle and the closed end of each extension portion disposed along the elongate length of the cover is spaced beyond the plane of the closed end of the cover a distance approximately equal to said fixed distance.

5. A cover as claimed in claim 4 in which each extension portion is of generally rectangular shaped configuration.

6. A cover as claimed in claim 5 in which the cover is formed of soft rubber material.

7. A cover as claimed in claim 6 in which the soft rubber material is EPDM rubber.

8. A cover as claimed in claim 5 including a tape fastener applied about the circumference of the cover along its elongate length when the cover is positioned over the receptacle so as to secure the cover to the receptacle.

9. A cover as claimed in claim 5 including at least one aperture formed in the cover along the elongate length thereof to permit drainage of water which may accumulate within the confines of the cover.

10. In combination with an electrical equipment receptacle having a length which includes projecting portions extending beyond a surface of the receptacle, a cover for said receptacle, said cover comprising, a body having an elongate length, said body having an open end and a closed end, the closed end being positioned within a plane spaced from the open end, a pair of extension portions disposed along opposite sides of the elongate length, each said extension portion having a respective open end coextensive with the open end of the cover and a closed end spaced beyond the plane of the closed end of the cover, the cover being adapted to be slidably positioned over the receptacle such that when the cover is so positioned the projecting portions of the receptacle are confined within the cover.

11. The combination as claimed in claim 10 in which the receptacle and the body of the cover are of generally cylindrical configuration.

12. The combination as claimed in claim 11 in which the elongate length of the cover is approximately equal to the length of the receptacle.

13. The combination as claimed in claim 12 in which the projecting portions of the receptacle extend a fixed distance beyond said surface of the receptacle and the closed end of each extension portion disposed along the elongate length of the cover is spaced beyond the plane of the closed end of the cover a distance approximately equal to said fixed distance.

14. The combination as claimed in claim 13 in which each extension portion is of generally rectangular shaped configuration.

15. The combination as claimed in claim 14 in which the cover is formed of soft rubber material.

16. The combination as claimed in claim 15 in which the soft rubber material is EPDM rubber.

17. The combination as claimed in claim 14 including a tape fastener applied about the circumference of the cover along its elongate length when the cover is positioned over the receptacle so as to secure the cover to the receptacle.

18. The combination as claimed in claim 14 including at least one aperture formed in the cover along the elongate length thereof to permit drainage of water which may accumulate within the confines of the cover.
